(19) United States
(12) Patent Application Publication
(10) Pub. No.: US 2003/0222272 A1
(43) Pub. Date: Dec. 4, 2003

(54) Semiconductor devices using minority carrier controlling substances

(76) Inventor: Roman J. Hamerski, Olathe, KS (US)

Correspondence Address: BLACKWELL SANDERS PEPER MARTIN LLP, TWO PERSHING SQUARE, 2300 MAIN STREET, SUITE 1000, KANSAS CITY, MO, 64108, US

(21) Appl. No.: 10/158,453

(22) Filed: May 30, 2002

(51) Int. Cl. H01L 29/866; H01L 29/88; H01L 29/74

(52) U.S. Cl. 257/106; 257/175

(57) ABSTRACT

A precision low-power crystalline semiconductor device is disclosed that has a crystalline structure. The semiconductor device has a semiconductor substrate layer of, for example N-type conductivity. The device also has a first region of doped semiconductor material that is also, for example, N-conductivity type. Further, the device has a second region of a doped semiconductor material having a conductivity that is, for example, P-type conductivity. Consistent with the present invention, the second region forms a P/N junction with the first region. Additionally, a noise-reducing minority carrier controlling substance is provided within the crystalline structure of the semiconductor device, and the substance imparts an operational parameter of a low-noise breakdown voltage at reverse currents below a threshold current.

### COPYRIGHT NOTICE AND AUTHORIZATION

A portion of the disclosure of this patent document contains material, which is subject to mask work protection. The mask work owner has no objection to the facsimile reproduction by anyone of the patent document or the patent disclosure, as it appears in the Patent and Trademark Office patent file or records, but otherwise reserves all mask work rights whatsoever.

### BACKGROUND OF INVENTION

Semiconductor devices are critical components in a vast array of modem products.

Purified crystalline semiconductor materials have highly useful electrical characteristics when specific types of impurities, called dopants, are introduced into the semiconductor's crystalline structure. Depending on the nature of the dopant introduced into the semiconductor material, the semiconductor material will take on a particular conductivity type, either P-type or N-type.

In connection with the present invention, to say that a material has one conductivity type that is consistent with another conductivity type means that both conductivity types are either P-type or N-type.

The element silicon is a an example of a semiconductor material. Pure silicon has four electrons in the valence shell of each of its atoms. Pure crystalline silicon forms a lattice structure, in which silicon's valence electrons form stable covalent bonds with other silicon atoms.

An example of P-type material is pure silicon doped with an impurity such as boron, aluminum, gallium, or indium. These materials are referred to as “acceptor” impurities because their valence shells contain only three electrons. When these materials are introduced into a semiconductor crystal, the uniform lattice structure of the silicon is affected because the three-electron valence shells of the doping material can't complete the lattice. The vacancy created by the lack of a fourth electron is called a hole. Holes are loosely held to the impurity atom so that, when affected by an electric field, electrons can drift into the hole, thus causing the hole to appear to drift. In this way, the hole acts as a positive-charge current carrier.

An example of N-type material is pure silicon doped with a very small amount of impurities containing five electrons in the valence shell. These materials can be antimony, phosphorus, or arsenic. Because of their extra electrons, they are called donor impurities. When these materials are blended with pure silicon, the uniform lattice structure of the silicon is affected because the five-electron valence shell of the doping material has too many electrons to simply complete the lattice structure. These extra electrons are loosely held to their impurity atoms so that, when affected by an electric field, the electrons can drift, thus acting as a negative-charge current carrier.

When a junction is formed between P material and N material, (“P/N junction”) the extra current carriers tend to cross the junction so that the lattice structure in the vicinity of the junction tends to have four electrons associated with each atom. The region where this phenomenon occurs is called the depletion region since both the P- and N-type materials have been depleted of their current carriers in this region.

In a P/N junction device, sometimes called a diode or rectifier, the electrode connected to the P-type material is referred to as the anode, and the electrode connected to the N-type material is called the cathode. The depletion region of a P/N junction has the useful property of causing a P/N junction device to conduct current when a positive voltage (above a forward voltage drop threshold) is applied across the P/N junction and to block the flow of current when a negative voltage is applied across the P/N junction. A positive voltage applied from anode to cathode is referred to as forward bias, and a negative voltage is referred to as reverse bias.

Accordingly, diodes conduct current from anode to cathode at forward biased voltages above the forward voltage drop, and diodes block current under reverse bias up to a point at which the diodes break down under a sufficiently high reverse biased voltage. Diodes that take advantage of breakdown characteristics are called Zener diodes.

Zener diodes have been used since the late 1950's as voltage references or for voltage regulation, originally as an alternative to the vacuum tube. Zener diodes have the useful property of blocking current under reverse bias, up to a threshold or breakdown voltage. When installed in parallel with a load, reverse biased Zener diodes clamp the voltage across the load at the Zener diode's breakdown voltage.

Zener diodes are P/N junction devices that are designed to operate nondestructively in reverse bias breakdown mode. While every P/N junction will break down under a sufficiently high reverse bias, a low-power rectifying diode will break down at a fairly high voltage and would likely be damaged by the resulting current. However, Zener diodes are designed to operate in breakdown mode, at specified currents, without sustaining damage.

A relatively lightly doped P/N junction will exhibit avalanche breakdown at the relatively high voltage of approximately 30V to 50V. Avalanche breakdown is the result of energizing thermally produced electron/hole pairs in the depletion region surrounding a P/N junction with the electric field associated with the reverse biased P/N junction. Given a sufficiently large electric field, energized electrons eventually take on enough energy to ionize atoms of the semiconductor material in the depletion region. Next, electrons that are released by ionization themselves become energized by the electric field, resulting in further ionization. The result of the chain reaction of ionization is the occurrence of sufficient numbers of charge carriers to enable the P/N junction to conduct electrical current. Observers have remarked that this chain reaction is like an avalanche on a snow covered mountain. Accordingly this type of breakdown is called avalanche breakdown.

Zener diodes are designed to break down at a specific voltage with a sharp reproducible characteristic. The diodes are designed to conduct the breakdown current nondestructively.

Zener diodes are generally used either as a voltage reference or as transient voltage suppressors. When used as voltage references, a high degree of precision is required for some electrical circuit designs. Accordingly, Zener diodes are frequently specified in terms of a +/− percentage error in breakdown voltage tolerance.

Known processes of manufacturing Zener diodes consist of fabricating them on thinly sliced wafers of crystalline semiconductor substrate. Conventional substrate wafers are formed with a high purity, monocrystalline, semiconductor material by a known monocrystalline growth method. In the growth method, a pool of doped molten liquid semiconductor material is seeded with a small semiconductor crystal. The seed is slowly drawn out of the pool, and as it is drawn out, the molten semiconductor atoms or molecules align with the lattice structure of the seed crystal to form a generally cylindrical ingot of semiconductor material. The crystalline semiconductor material can also be fabricated with known float zone methods. The ingot is then sliced into generally circular substrate wafers, of a conductivity type determined by the dopant type and concentration introduced into the molten semiconductor.

Ideally, each such semiconductor wafer has precisely the same doping concentration and resistivity. However, in practice, this is not the case. Because of inherent properties of dopant materials and the way the dopant materials are introduced into the semiconductor material there are differences in dopant concentration and resistivity along the length of a semiconductor ingot.

Further, there are also differences in dopant concentration and resistivity across each wafer.

There are several known processes for modifying the physical properties and conductivity properties of various regions of a substrate wafer to fabricate a semiconductor device. Diffusion is the process of heating the substrate in the presence of a material containing atoms to be diffused into the substrate. For instance, a conventional way to fabricate a P-type layer on an N-type substrate is to use planar dopant sources. Silicon wafers are heated facing the dopant source wafers. Over time, a layer of B₂O₃ covers the silicon wafers and boron diffuses into the N-type substrate creating a layer of P-type material. Because of the high temperatures at which the diffusion process is performed, the boron atoms are able to replace silicon atoms in the silicon crystal structure. Parameters including the concentration of the dopant gas and the amount of time of the diffusion control the depth of the layer and the concentration of the dopant.

Another way to form a layer on a substrate is using epitaxy. Epitaxial deposition methods involve growing a layer of material by gradually adding a combination of silicon and dopant atoms to the surface of the substrate so that the added atoms maintain the same crystal structure as the substrate.

Another way to form a layer in an existing semiconductor material is by way of ion implantation. In ion implantation, individual ions of dopant materials are accelerated to great speeds and shot into the semiconductor material. By altering the energy at which ions are implanted, the depth of implantation can be controlled. Further, through ion implantation, the concentration or dose of dopants to be introduced can be closely controlled. As contrasted with diffusion, ion implantation can be performed without heating the substrate to high temperatures.

When a Zener diode is reverse biased, there is very little leakage current until the reverse biased voltage across the diode approaches V_{Z}, the breakdown voltage of the Zener diode. Once the current through the Zener diode reaches I_{Z}, the voltage drop across the Zener diode remains essentially equal to V_{Z}. Accordingly, reverse biased voltages above V_{Z} are clamped to the level of V_{Z}. Energy associated with current I_{Z} that is sunk by the Zener diode in order to clamp the voltage to V_{Z} is dissipated as heat from the Zener diode. Circuit designers can use series resistance between a voltage source and the Zener diode to limit the I_{Z} current to an acceptable level. For larger values of operational I_{Z}, it is necessary to ensure that the semiconductor device and its packaging are sufficiently capable of dissipating heat energy. Dynamic impedance is the voltage rate of change with respect to current (ZZ=dV/dI). Because the voltage regulator Zener diode's main function is to provide constant voltage output, the dynamic impedance is preferably as low as possible, along the operating portion of the voltage to current curve.

Known Zener diodes and methods of manufacturing Zener diodes result in devices that exhibit noise at low currents. Accordingly, regardless of the precision of Zener diodes at nominal currents of approximately 1 mA or above, the diodes are not precise voltage references if the reverse current (I_{Z}) is too low. Accordingly, a method for controlling the noise in a Zener diode at low reverse currents is needed.

### SUMMARY OF INVENTION

A precision low-power crystalline semiconductor device is provided that has a crystalline structure. The semiconductor device has a semiconductor substrate layer of, for example N-type conductivity. The device also has a first region of doped semiconductor material that is also, for example, N-conductivity type. Further, the device has a second region of a doped semiconductor material having a conductivity that is, for example, P-type conductivity. Consistent with the present invention, the second region forms a P/N junction with the first region. Additionally, a noise-reducing minority carrier controlling substance is provided within the crystalline structure of the semiconductor device, and the substance imparts an operational parameter of a low-noise breakdown voltage at reverse currents at which the device is just starting to regulate voltage.

In one embodiment, the minority carrier controlling substance is gold. In an alternative embodiment, the minority carrier controlling substance is platinum. The dynamic impedance associated with the semiconductor device is optionally more than approximately 50% reduced.

A method of manufacturing a semiconductor device is also provided. The method includes depositing an epitaxial layer on a semiconductor substrate that is doped with material of, for example N-type conductivity. Next, interior dopant ions are implanted, the interior dopant ions entering the crystal structure of the epitaxial layer and the substrate forming an interior region extending through the epitaxial layer and into the substrate. Next, junction dopant ions are implanted that form a junction layer that provides an interior P/N junction with the interior region and the junction layer forming a peripheral P/N junction with a peripheral portion of the device. Next, a layer of minority carrier controlling substance is deposited on the back of the device. Further, the minority carrier controlling substance is diffused into the device. In one embodiment, the interior dopant ions are implanted at an energy of greater than 40 KeV. A low-power consumer electronic product is also provided that employs at least one low-noise semiconductor device.

### BRIEF DESCRIPTION OF DRAWINGS

FIG. 1 is a cross sectional side elevation view of a minority carrier controlling semiconductor consistent with the present invention;

FIG. 2 is a cross sectional side elevation view of a semiconductor wafer with an epitaxial layer and two oxide layers;

FIG. 3 is a cross sectional side elevation view of the semiconductor structure of FIG. 2 with an etched opening in one of the oxide layers;

FIG. 4 is a cross sectional side elevation view of the semiconductor structure of FIG. 3 including an ion implant region;

FIG. 5 is a cross sectional side elevation view of the semiconductor structure of FIG. 4 in which the ion implant region is diffused using thermal diffusion;

FIG. 6 is a cross sectional side elevation view of the semiconductor structure of FIG. 5 with an enlarged etched opening in an oxide layer;

FIG. 7 is a cross sectional side elevation view of the semiconductor structure of FIG. 6 including an ion implant region corresponding to the etched opening illustrated in FIG. 6;

FIG. 8 is a cross sectional side elevation view of the semiconductor structure of FIG. 7 including oxide layers;

FIG. 9 is a cross sectional side elevation view of the semiconductor structure of FIG. 8 in which the oxide layers are removed from the back of the semiconductor structure;

FIG. 10 is a cross sectional side elevation view of the semiconductor structure of FIG. 9 in which a minority carrier controlling dopant is deposited on the back of the semiconductor structure;

FIG. 11 is a cross sectional side elevation view of the semiconductor structure of FIG. 10 in which an opening is etched in the oxide layer and a metal layer deposited on the front of the semiconductor structure; and

FIG. 12 is a cross sectional side elevation view of the semiconductor structure of FIG. 11 in which portions of the front metal are etched away.

For the purpose of clarity in illustrating the characteristics of the present invention, accurate proportional relationships of the elements thereof have not been maintained in the Figures. Further, the sizes of certain small devices and elements thereof have been exaggerated.

### DETAILED DESCRIPTION

The present invention involves semiconductors, such as single P/N junction Zener diodes, that are, for example, diffused with a minority carrier controlling substance such as gold or platinum in order to greatly reduce noise at even very low current levels. As a result, the inventive Zener diodes can be used in applications involving very small reverse breakdown currents.

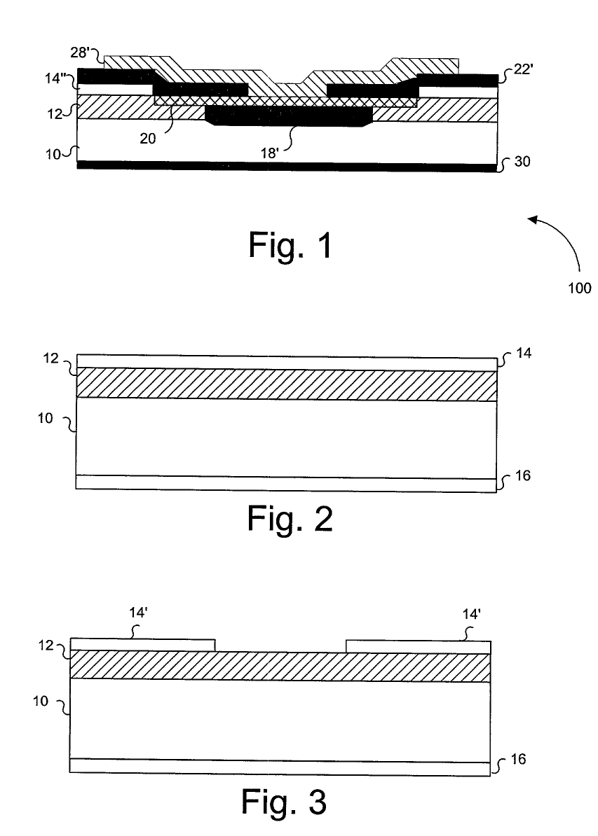

FIG. 1 is a cross sectional side elevation view of a Zener diode including a minority carrier controlling substance. The Zener diode 100 includes a substrate 10, an epitaxial layer 12, interior region 18, and a junction layer 20. Zener diodes manufactured according to the invention operate, for example, as voltage regulators in consumer electronics such as televisions or low-power portable electronic devices.

FIG. 2 is a cross sectional side elevation view of a semiconductor wafer with an epitaxial layer and two oxide layers. In one embodiment, substrate 10 is low resistivity, N⁺-type <111>orientation monocrystalline silicon having a resistivity in the range of approximately 1E-3 ohm-cm cm to 5E-3 ohm-cm. In an alternative embodiment, the substrate 10 is comprised of other types of semiconductor material, such as gallium arsenide. Further, it is understood that a P-type substrate can also be used with corresponding adjustments to the fabrication process.

In one embodiment, the N⁺-type silicon substrate is doped with arsenic. In an alternative embodiment, antimony is used to dope the silicon. It is understood that other dopants can also be used.

In one embodiment, N-type layer 12 is deposited using Chemical Vapor Deposition (“CVD”) epitaxy techniques. Alternatively, other processes for growing an epitaxial layer are employed, such as molecular beam epitaxy. In one embodiment, layer 12 is an approximately 10 micron thick epitaxial layer of phosphorous doped silicon having a resistivity of approximately 5 ohm-cm with a doping concentration of approximately 9.2E14 atoms/cm³.

Other N-type dopants are used if desired, and alternatively, the resistivity of layer 12 can range from 1 ohm-cm to 30 ohm-cm. In one embodiment, a resistivity of approximately 5 ohm-cm is chosen because of the reproducability of epitaxial layer generation of this concentration.

Next, the wafer is put through a high temperature diffusion process. In this process, an oxide layer is grown on the surface of layer 12 and on the back of the wafer, forming layers 14 and 16 respectively. The oxide layers are produced by exposing the wafer to an environment of approximately 1000° C. for a time of about 200 minutes and to approximately 1200° C for an additional 200 minutes. During this time, the heated semiconductor materials are exposed to a mixture of nitrogen and oxygen gas. In one embodiment, a layer of silicon dioxide ranging in thickness from about 1400 Å to about 1800 Å, preferably approximately 1600 Å is grown on the surfaces of the wafer. It is understood that other processes for forming an oxide layer can be used in connection with the present invention. Further, the oxide layer can be of a different thickness without departing from the practice and teaching of the present invention.

In one embodiment, through the heating process in which the oxide layer is grown, a phosphorous dopant in layer 12 diffuses into the substrate and into the oxide reducing the dopant concentration in layer 12. In one embodiment, the higher concentration arsenic dopant from the substrate diffuses into the epitaxial layer 12. However, because arsenic has a relatively lower diffusion coefficient than phosphorous, the resulting arsenic diffusion is shallower than the corresponding phosphorous diffusion. Therefore, approximately 30% or more of the top portion of the epitaxial layer 12 experiences a net loss of dopant atoms causing its resistivity to increase.

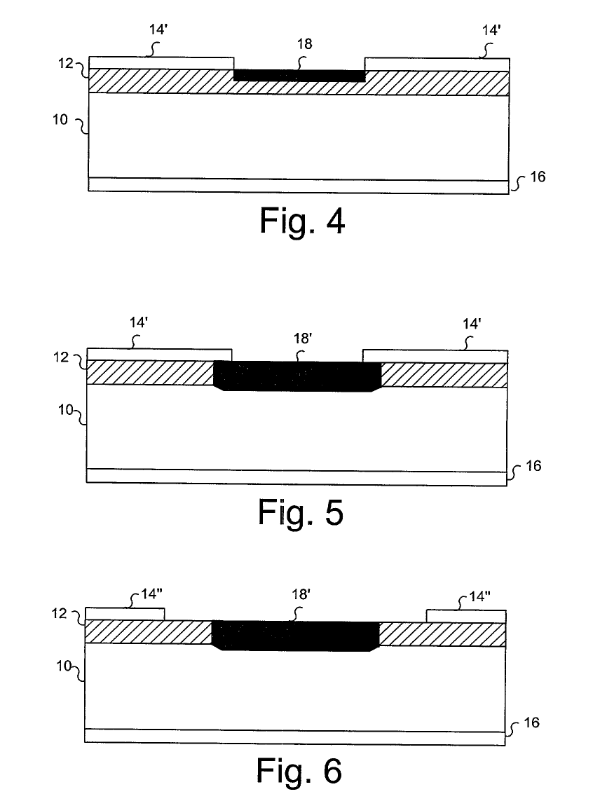

Because of the differences in the depths of diffusion between arsenic and phosphorous, there is a negligible sensitivity in the Zener diode voltage (V_{Z}) to variations in the initial resistivity of the epitaxial layer 12. Accordingly, devices and methods consistent with the present invention provide excellent control of V_{Z} based on the dose of the phosphorous implant, which is further described in connection with FIG. 4. In addition to facilitating diffusion, heating of the epitaxial layer causes the phosphorous dopant to become thermally activated within the semiconductor crystalline structure.

FIG. 3 is a cross sectional side elevation view of the semiconductor structure of FIG. 2 with an etched opening in one of the oxide layers. A photolithography step is performed to create an opening in the oxide layer. First, a photoresist material is applied to the surface of the oxide layer. In one embodiment, the photoresist is applied at a thickness of about 1.3 microns.

The photoresist is exposed to light through a pattern mask, and the exposed portions of the photoresist material are then removed from the surface of the oxide layer. In one embodiment, the oxide is etched from the surface of the epitaxial layer using a Reactive Ion Etching (“RIE”) technique according to the pattern detail that was transferred to the photoresist. Oxide regions under the photoresist covered areas are not removed in the etching process.

In one embodiment, a circular window of approximately 86 microns is etched into the oxide layer. In an alternative embodiment, a square window with rounded corners is etched into the oxide layer. In the cross section illustrated in FIG. 3, layer 14′ is a layer of the oxide material having an opening formed by the above described photolithography step. Layer 14′ is associated with the unexposed photoresist that remains on the wafer after the photolithography development process and the oxide etching process. In one embodiment, the remaining photoresist layer is removed from the wafer with a photoresist stripping solution. In an alternative embodiment, it is not removed until the wafer is subjected to further processing.

FIG. 4 is a cross sectional side elevation view of the semiconductor structure of FIG. 3 including an ion implant region. Junction region 20 is formed using ion implantation of, for example, phosphorous, an N-type dopant, at a dose of 1.72E13 ions/cm2 at an energy of 140 KeV, forming a layer approximately 1 micron deep. In an alternative embodiment, significantly lower energy is used in the phosphorous ion implantation process. In one embodiment, the ion implantation produces a layer of phosphorous doped semiconductor material that is thinner than layer 12. In one embodiment, any remaining photoresist material is removed from the surface of the wafer.

During the process of ion implantation, the region in which an opening has been made in the oxide will be exposed to ions fired into the semiconductor material at high energies. In the regions where the oxide has not been etched away, the oxide will absorb the ions and not permit them to enter into the semiconductor material. The oxide is a good insulator, and unlike pure silicon, its characteristics are not materially altered by the presence of dopant atoms embedded into the oxide material.

In an alternative embodiment, the remaining photoresist material of approximately 1.3 microns in thickness is left on the wafer until after an ion implantation procedure to aid the oxide in absorption of ions in the region outside of the exposed window.

FIG. 5 is a cross sectional side elevation view of the semiconductor structure of FIG. 4 in which the ion implant region is diffused using thermal diffusion. The process of thermal diffusion involves heating the semiconductor wafer. During, the heating process, internal layer 18 diffuses outward to form internal region 18′. Further, another layer of oxide (not shown) is deposited on the surface of the wafer.

In one embodiment, the oxide layer is produced by exposing the wafer to an environment of approximately 1000° C. for a time of about 200 minutes and to approximately 1200° C. for an additional 200 minutes. During this time the heated semiconductor materials are exposed to a mixture of nitrogen and oxygen gas. In one embodiment, a layer of silicon dioxide ranging in thickness from about 1400 Å to about 1800 Å, preferably approximately 1600 Å is grown on the surface of the phosphorous ion implant doped epitaxial layer. Additional oxide is grown on the portions of the wafer already covered with oxide, however, only approximately 700 Å, for example, grows on the preexisting oxide layer.

FIG. 6 is a cross sectional side elevation view of the semiconductor structure of FIG. 5 with an enlarged etched opening in an oxide layer. In one embodiment, photolithography is used to etch an opening in the newly deposited oxide. In one embodiment, the etched opening has an approximately circular geometry of a size larger than the initial opening through which the ion implantation process was performed in connection with the layer 18. As in the previous photolithography process, the photoresist may be removed from the wafer or it may be left on the wafer. In one embodiment, it is left on the wafer until after the next ion implantation step is completed. As shown in FIG. 6, an opening in oxide Layer 14″ is formed using, for example, photolithography.

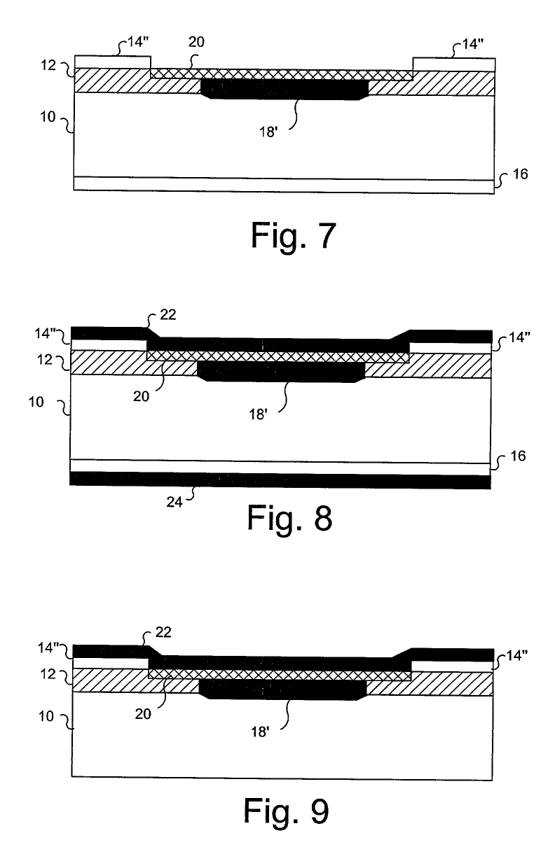

FIG. 7 is a cross sectional side elevation view of the semiconductor structure of FIG. 6 including an ion implant region corresponding to the etched opening illustrated in FIG. 6. Layer 20 is preferably a P-type layer of semiconductor material formed preferably by ion implantation. In one embodiment, the layer 20 is formed by implanting a relatively small dose of a P-type dopant such as boron, at a relatively high energy. In one embodiment, a first implantation is performed with a dose of approximately 6E14 ions/cm2 at an energy of approximately 40 KeV.

In an embodiment, layer 20 comprises an additional layer, which is formed in connection with a P-type dopant, for example, a second boron ion implantation with a larger dose of boron at a lower energy. In this embodiment, the low energy boron ion implantation step is performed with a dose of approximately 1E15 ions/cm2 at an energy of approximately 10 KeV.

The low energy boron ion implantation step associated with the lower-energy layer (not shown) serves the purpose of forming a region having low contact resistance. Low contact resistance at the interface with an electrode reduces the forward voltage drop and facilitates the production of Zener diodes having precise breakdown voltages. Conversely, a high contact resistance increases the forward voltage drop and results in variations in Zener diode breakdown voltages. Accordingly, in a preferred embodiment a low energy boron ion implantation is used.

The higher energy boron ion implant step is optional and useful for maximizing the breakdown voltage in the periphery of the boron implanted region extending peripherally beyond the region 18′.

FIG. 8 is a cross sectional side elevation view of the semiconductor structure of FIG. 7 including oxide layers. After the P-type dopant is implanted, another oxide layer 22 is grown on the front surface of the wafer. Further an oxide layer 24 is also formed on the back of the wafer. In one embodiment, the layers 22 and 24 are comprised of silicon dioxide ranging in thickness from between about 2000 Å and about 4000 Å. The silicon dioxide is deposited on the surfaces of the wafer using, for example a CVD process. In one embodiment, an approximately 3000 Å thick layer is deposited at a temperature of approximately 890° C. In an alternative embodiment, a nitride deposition is performed in connection with a CVD process at a temperature of approximately 800° C.

FIG. 9 is a cross sectional side elevation view of the semiconductor structure of FIG. 8 in which the oxide layers 16 and 24 are removed from the back of the semiconductor structure. In one embodiment the layers 16 and 24 are stripped from the wafer using, for example, hydrofluoric acid. The oxide is removed so that a minority carrier controlling substance can be introduced into the semiconductor crystal structure.

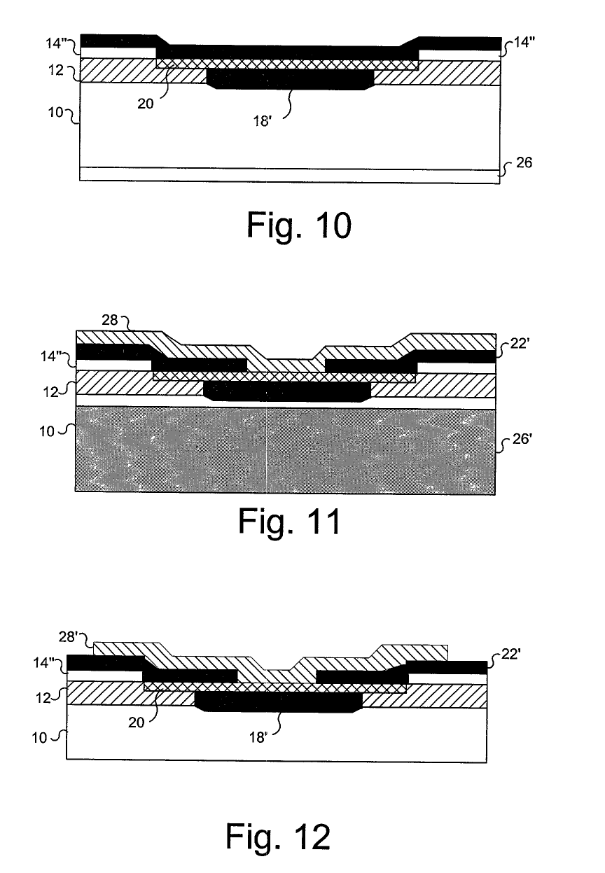

FIG. 10 is a cross sectional side elevation view of the semiconductor structure of FIG. 9 in which a minority carrier controlling substance is deposited on the back of the semiconductor structure. Layer 26 is a minority carrier controlling substance, such as gold that is deposited on the wafer using for example sputter techniques. In one embodiment, the layer 26 is gold deposited in a thickness of approximately 250 Å.

FIG. 11 is a cross sectional side elevation view of the semiconductor structure of FIG. 10 in which an opening is etched in the oxide layer and a metal layer deposited on the front of the semiconductor structure. In the oxide layer 22 of FIG. 10, an opening is formed using, for example, photolithography to form a contact opening. Further, a layer 28 is deposited on the front surface of the semiconductor structure. Additionally, layer 26 is diffused into the substrate 10 to form region 26′ in which a minority carrier controlling substance, such as gold, is diffused into the crystal structure of the substrate 10. In one embodiment, gold is diffused into the substrate 10 at approximately 900° C. to approximately 925° C., for 45 minutes. In one embodiment, the minority carrier controlling substance is diffused throughout the entire wafer.

In this embodiment, region 26′ is larger than illustrated in FIGS. 11 and 12, extending throughout the semiconductor structure from front to back of the wafer.

FIG. 12 is a cross sectional side elevation view of the semiconductor structure of FIG. 11 in which portions of the front metal are etched away. Layer 28′ is formed by etching away portions of layer 28 to form a an anode metal pad with portions of metal removed at the device periphery to facilitate cutting the device out of the wafer. Additionally, the wafer is optionally ground down from the back side from approximately 630 μm to approximately 220 μm.

Further, as illustrated in FIG. 1, back metal 30 is applied using, for example, sputter techniques.

The present invention has been disclosed in connection with an illustrative Zener diode.

However, noise reduction principles consistent with the practice and teaching of the present invention can b used in connection with other types of Zener diodes, and more generally, with other types of semiconductor structures, that for example, include precise voltage or current references.

When a Zener diode is used as a voltage regulator, an electric field exists in the depletion region having a field magnitude based on the level of reverse bias of the P/N junction. Once the electric field reaches a critical field level, Ecrit, breakdown of the junction occurs. Even before the breakdown actually takes place, there is some multiplication of carriers within the depletion region, resulting from thermally released charge carriers and the electric field in the P/N junction. If I_{RO} is defined to be the reverse current, absent any breakdown producing mechanism, then the actual reverse current I_{R} is given by: I_{R}=M×I_{RO}, where M is the multiplication factor. Breakdown of the junction occurs when M becomes very large.

The invention uses gold, platinum, or any other substance that reduces minority carrier lifetime to make the Multiplication Factor M a more abrupt function of reverse bias. Namely, by introducing minority carrier recombination centers, the average free path for minority carriers is reduced. That causes M to be reduced before full-scale multiplication takes place in connection with an electric field that well exceeds the critical field Ecrit.

A similar phenomenon is responsible for an increase in the breakdown voltage of the P/N junction diode when the temperature of a diode is increased. Increased thermal vibrations of the atoms of the semiconductor crystal lattice cause a reduction in the minority carrier diffusion length, because there is greater opportunity for an arbitrary charge carrier to collide with a vibrating atom in the crystal structure. Reduced diffusion length suppresses the process of avalanche multiplication, because in travelling a shorter path, there is less chance that an arbitrary charge carrier will cause the generation of an additional charge carrier. Accordingly, when the temperature is increased, higher reverse bias is needed to increase the electric field to a level sufficient to increase multiplication of carriers within the depletion region so as to reach the level of reverse current corresponding to the breakdown voltage.

Consistent with the present invention, suppression of carrier multiplication with minority carrier reducing substances, such as gold, greatly reduces the noise level caused by the action of minority carriers. This noise reduction reduces dynamic impedance for very low reverse currents. Experimentally, a Zener diode that shows significant noise for I_{Z}=approximately 350 μA becomes essentially noise free at an I_{Z} of 20 μA. The minority carrier controlling substance diffusion is accomplished, for example, by depositing 250 Å of gold on the bare back of a silicon wafer and heating it at approximately 925° C. for approximately 45 minutes.

While exemplary embodiments and particular applications of this invention have been shown and described, it is apparent that many other modifications and applications of this invention are possible without departing from the inventive concepts herein disclosed. It is, therefore, to be understood that, within the scope of the appended claims, this invention may be practiced otherwise than as specifically described, and the invention is not to be restricted except in the spirit of the appended claims. Though some of the features of the invention may be claimed in dependency, each feature has merit if used independently.

1. A precision low-power crystalline semiconductor device having a crystalline structure, the semiconductor device comprising:
a semiconductor substrate layer of a substrate conductivity type and of a substrate resistivity;
an first region of doped semiconductor material having a first conductivity type consistent with the substrate conductivity type;
a second region of a doped semiconductor material having a conductivity type different from the substrate conductivity type, the second region forming a P/N junction with the first region; and
a noise-reducing minority carrier controlling substance within the crystalline structure of the semiconductor device, the substance imparting an operational parameter of a low-noise breakdown voltage at reverse currents below a threshold current.

2. The semiconductor device according to claim 1, wherein the substrate and first region are of an N-type conductivity type.

3. The semiconductor device according to claim 1, wherein the second region is of a P-type conductivity type.

4. The semiconductor device according to claim 1, wherein the minority carrier controlling substance is gold.

5. The semiconductor device according to claim 1, wherein the minority carrier controlling substance is platinum.

6. The semiconductor device according to claim 1, wherein a dynamic impedance associated with the semiconductor device is more than approximately 50% reduced.

7. The semiconductor device according to claim 1, wherein the threshold current is approximately 1 mA.

8. The semiconductor device according to claim 1, wherein, the threshold current is approximately 350 μA

9. A method of manufacturing a semiconductor device, the method comprising:
depositing an epitaxial layer on a semiconductor substrate, the substrate doped with material of a substrate dopant type, the substrate having a substrate resistivity;
implanting interior dopant ions of an interior region dopant type consistent with the substrate dopant type, the interior dopant ions entering the crystal structure of the epitaxial layer and the substrate forming an interior region extending through the epitaxial layer and into the substrate;
implanting junction dopant ions of a junction dopant type different from the substrate dopant type the junction dopant ions entering a crystal structure of the epitaxial layer and forming a junction layer, the junction layer forming an interior P/N junction with the interior region and the junction layer forming a peripheral P/N junction with a peripheral portion of the device;
depositing a layer of minority carrier controlling substance onto of the device; and
diffusing the minority carrier controlling substance into the device.

10. The method as set forth in claim 9, wherein the interior dopant ions are implanted at an energy of greater than 40 KeV.

11. The method as set forth in claim 9, wherein the interior dopant ions are acceptor dopant ions.

12. The method as set forth in claim 11, wherein the acceptor dopant ions are comprised of phosphorous.

13. The method as set forth in claim 9, wherein the junction dopant ions are donor dopant ions.

14. The method as set forth in claim 13, wherein the donor dopant ions are comprised of boron.

15. The method as set forth in claim 9 further comprising implanting a low contact resistance layer into an exterior surface of the junction layer at a lower energy than used in connection with forming the junction layer.

16. The method as set forth in claim 9 further comprising at least one longer duration high temperature heating process to diffuse and activate the interior dopant ions.

17. The method as set forth in claim 9 further comprising at least one shorter duration high temperature heating process to activate the junction dopant ions.

18. The method as set forth in claim 9, wherein the minority carrier controlling substance is gold.

19. The method as set forth in claim 9, wherein the minority carrier controlling substance is platinum.

20. A low-power consumer electronic product comprising:
a housing operable to enclose and to protect components internal to the product; and
electrical circuitry operable to provide electrical signals to an associated user interface, the electrical circuitry including a low-power Zener diode comprising:
a semiconductor substrate layer of a substrate conductivity type and of a substrate resistivity;
an first region of doped semiconductor material having a first conductivity type consistent with the substrate conductivity type;
a second region of a doped semiconductor material having a conductivity type different from the substrate conductivity type, the second region forming a P/N junction with the first region; and
a noise-reducing minority carrier controlling substance within the crystalline structure of the semiconductor device, the substance imparting an operational parameter of a low-noise breakdown voltage at reverse currents below a threshold current.
